(19) United States
(12) Patent Application Publication
(10) Pub. No.: US 2023/0353261 A1
(43) Pub. Date: Nov. 2, 2023

(54) Method for measuring power of received signal

(71) Applicant: REALTEK SEMICONDUCTOR CORPORATION, HSINCHU (TW)

(72) Inventors: WEI-CHIEH HUANG, Hsinchu (TW); KUN-CHIEN HUNG, Hsinchu (TW)

(21) Appl. No.: 18/125,508

(22) Filed: Mar. 23, 2023

(30) Foreign Application Priority Data
Mar. 31, 2022 (TW) 111112658

(51) Int. Cl. H04B 17/318; H03M 1/18

(52) U.S. Cl. CPC H04B 17/318; H03M 1/185

(57) ABSTRACT

A method for measuring power of a received signal includes the following steps: determining N type(s) of sampling rate(s) of an analog-to-digital converter (ADC) according to a theoretical minimum sampling rate of the received signal; using the ADC to sample the received signal according to the N type(s) of sampling rate(s) within a period of sampling time and thereby obtaining sampling results; and measuring the power of the received signal according to the sampling results and the period of sampling time, wherein the theoretical minimum sampling rate is corresponding to a signal cycle of the received signal, the N is a positive integer, the N type(s) of sampling rate(s) is/are corresponding to N type(s) of sampling cycle(s), and any of the N type(s) of sampling cycle(s) and the signal cycle are coprime.

### BACKGROUND OF THE INVENTION

### 1. Field of the Invention

The present disclosure relates to a method for measuring the power of a received signal, especially to a method for measuring the power of a received signal at an extraordinarily low sampling rate.

### 2. Description of Related Art

In order to ascertain whether any wireless signal is transmitted over a specific frequency band, a general wireless receiver usually measures the power of wireless signals of the specific frequency band, if any. To measure the power of a wireless signal of the specific frequency band, the wireless receiver samples the wireless signal and generates sampling results that are sufficient to represent the wireless signal, and then the wireless receiver measures the power of the wireless signal according to the sampling results.

According to the Sampling Theorem, if a wireless signal is periodic and transmitted over a bandwidth BW, a wireless receiver using a real-number sampler is supposed to sample the wireless signal at a sampling rate not less than 2BW to generate sampling results that are sufficient to represent the wireless signal. However, this sampling rate may be high, and the high sampling rate results in increases in power consumption, hardware requirements, and cost of the wireless receiver.

It is noted that even though the aforementioned wireless receiver samples the wireless signal with a complex-number sampler composed of a real-part sampler and an imaginary-part sampler, the wireless receiver is supposed to sample the wireless signal at a sampling rate not less than BW according to the Sampling Theorem, and the wireless receiver may still has the aforementioned problems if the sampling rate is high.

### SUMMARY OF THE INVENTION

An object of the present disclosure is to provide a method for measuring the power of a received signal without the problems of the prior art.

An embodiment of the method of the present disclosure is applicable to a circumstance that the signal cycle of a received signal can be ascertained. This embodiment includes the following steps: determining N type(s) of sampling rate(s) of an analog-to-digital converter (ADC) according to the signal cycle of the received signal; obtaining sampling results from the ADC sampling the received signal according to the N type(s) of sampling rate(s) within a period of sampling time; and measuring the power of the received signal according to the sampling results and the period of sampling time, wherein the N is a positive integer and the N type(s) of sampling rate(s) correspond(s) to N type(s) of sampling cycle(s). It is noted that the signal cycle (α × ΔT) is equivalent to a product of a signal-cycle coefficient (α) and a unit of time (ΔT), any of the N type(s) of sampling cycle(s) is equivalent to a product of a sampling-cycle coefficient (β) and the unit of time (ΔT), and the signal-cycle coefficient and the sampling-cycle coefficient are coprime. It is also noted that the sampling-cycle coefficient varies with the type of sampling cycle.

Another embodiment of the method of the present disclosure is applicable to a circumstance that the signal cycle of a received signal is uncertain or not required. This embodiment includes the following steps: using an ADC to sample the received signal according to multiple types of sampling rates within a period of sampling time and thereby obtaining sampling results, wherein the multiple types of sampling rates are corresponding to multiple types of sampling cycles, and the multiple types of sampling cycles are coprime to one another; and measuring the power of the received signal according to the sampling results and the period of sampling time.

Another embodiment of the method of the present disclosure is applicable to a circumstance that the signal cycle of a received signal is uncertain or not required. This embodiment includes the following steps: using an ADC to sample the received signal according to N types of sampling intervals within a period of sampling time and thereby obtaining sampling results, wherein the N types of sampling intervals are determined randomly and the N is an integer greater than one; and measuring the power of the received signal according to the sampling results and the period of sampling time.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an exemplary wireless receiver for performing the method of the present disclosure.

FIG. 2 shows a received signal and incomplete sampling results of the received signal.

FIG. 3 shows an embodiment of the method of the present disclosure for measuring the power of a received signal.

FIG. 4 shows sampling results obtained with the method of FIG. 3.

FIG. 5 shows another embodiment of the method of the present disclosure for measuring the power of a received signal.

FIG. 6 shows yet another embodiment of the method of the present disclosure for measuring the power of a received signal.

FIG. 7 shows sampling results obtained with the method of FIG. 6.

### DETAILED DESCRIPTION OF THE PREFERRED EMBODIMENTS

The present specification discloses a method for measuring the power of a received signal. This method can measure the power of the received signal at an extraordinarily low sampling rate regardless of the Sampling Theorem.

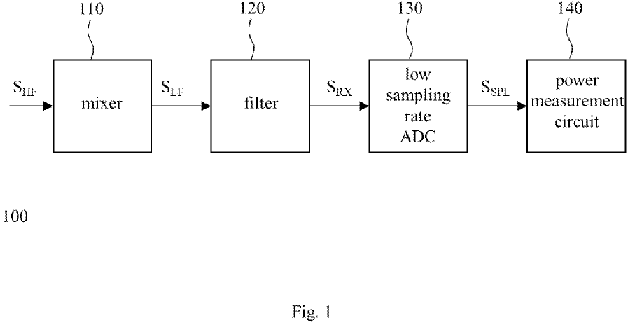

FIG. 1 shows an exemplary wireless receiver for performing the method of the present disclosure. The wireless receiver 100 of FIG. 1 includes a mixer 110, a filter 120, a low sampling rate analog-to-digital converter (ADC) 130, and a power measurement circuit 140. The mixer 110 is configured to generate a low frequency signal S_{LF} according to a high frequency signal S_{HF}, wherein the high frequency signal S_{HF} originates from a wireless signal received by an antenna (not shown in FIG. 1). The filter 120 is configured to generate a received signal S_{RX} according to the low frequency signal S_{LF}. The low sampling rate ADC 130 is configured to sample the received signal S_{RX} according to one or multiple sampling rate(s) fs (i.e., one or multiple sampling cycle(s) Ts) and thereby generate sampling results S_{SPL}. The power measurement circuit 140 is configured to measure the power of the received signal S_{RX} according to the sampling results S_{SPL}. It is noted that if the bandwidth of the received signal S_{RX} is BW, the minimum sampling rate ƒ_{S_MIN} (hereinafter referred to as “the theorical minimum sampling rate”) for sampling the received signal S_{RX} is supposed to be not lower than 2BW (when the low sampling rate ADC 130 uses a real-number sampler) or BW (when the low sampling rate ADC 130 uses a complex-number sampler composed of a real-part sampler and an imaginary-part sampler) according to the Sampling Theorem; however, the present method allows the low sampling rate ADC 130 to sample the received signal at a sampling rate ƒ_{S} lower than the theorical minimum sampling rate ƒ_{S_MIN} to reduce the total sampling times and consequently reduce the power consumption of the wireless receiver 100. It is also noted that even though the theorical minimum sampling rate ƒ_{S_MIN} is uncertain, a possible value of the theorical minimum sampling rate ƒ_{S_MIN} can be estimated according to the design and purpose of the wireless receiver 100; accordingly, the low sampling rate ADC 130 can use the sampling rate(s) ƒ_{S} lower than the possible value to reduce the power consumption of the wireless receiver 100.

On the basis of the above description, the low sampling rate ADC 130 is allowed to sample the received signal S_{RX} at a sampling rate ƒ_{S} lower than the theorical minimum sampling rate ƒ_{S_MIN}; however, this sampling rate ƒ_{S} should be determined conditionally rather than arbitrarily. To be more specific, if the low sampling rate ADC 130 samples the received signal S_{RX} at an inadequate sampling rate

$$\left(\text{e} \text{.g} \text{.,} \frac{{f}_{S \text{\_} M I N}}{2}\right)$$

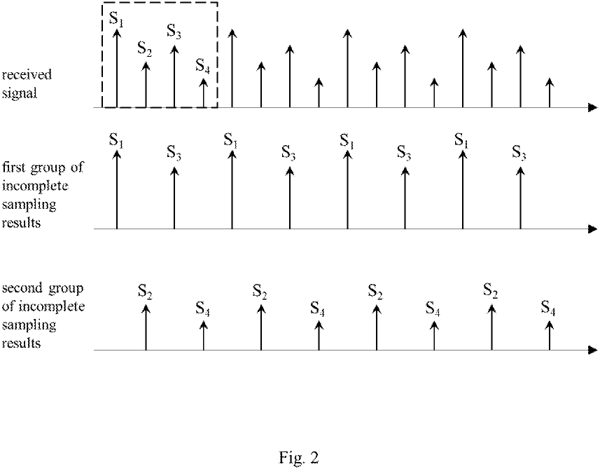

lower than the theorical minimum sampling rate ƒ_{S_MIN}, the low sampling rate ADC 130 will generate incomplete sampling results S_{SPL} incapable of representing the received signal S_{RX}; as a result, the power measurement circuit 140 cannot measure the power of the received signal S_{RX} correctly. For example, FIG. 2 shows a first group of incomplete sampling results of the received signal S_{RX} and a second group of incomplete sampling results of the received signal S_{RX}. As shown in FIG. 2, the received signal S_{RX} is a periodic signal (as illustrated with the dashed box in FIG. 2) and can be represented by four sampling results S₁, S₂, S₃, and S₄, wherein the height of each sampling result is linearly/nonlinearly proportional to the power of this sampling result. The first group of incomplete sampling results is obtained according to a sampling rate

$$\frac{{f}_{S \text{\_} M I N}}{2}$$

and only includes the first sampling result S₁ and the third sampling result S₃ of the four sampling results S₁, S₂, S₃, and S₄; since the average power of the two sampling results S₁ and S₃ is higher than the average power of the four sampling results S₁, S₂, S₃, and S₄, an average power of the received signal S_{RX} measured by the power measurement circuit 140 according to the first group of incomplete sampling results is higher than the actual average power of the received signal S_{RX}. The second group of incomplete sampling results is obtained according to a different starting sampling point but the same sampling rate

$$\frac{{f}_{S \text{\_} M I N}}{2} ,$$

and only includes the second sampling result S₂ and the fourth sampling result S₄ of the four sampling results S₁, S₂, S₃, and S₄; since the average power of the two sampling results S₂ and S₄ is lower than the average power of the four sampling results S₁, S₂, S₃, and S₄, an average power of the received signal S_{RX} measured by the power measurement circuit 140 according to the second group of incomplete sampling results is lower than the actual average power of the received signal S_{RX}. In consideration of the above, although the first/second group of incomplete sampling results is obtained according to a sampling rate

$$\frac{{f}_{S \text{\_} M I N}}{2}$$

lower than the theorical minimum sampling rate ƒ_{S_MIN}, each of the first and second groups of incomplete sampling results cannot fully represent the received signal S_{RX}.

In light of the above, the sampling rate ƒ_{S} of the low sampling rate ADC 130 should be lower than the theorical minimum sampling rate fs ƒ_{S_MIN} to reduce the power consumption of the wireless receiver 100, and should be determined adequately as mentioned in the following paragraphs to ensure that the low sampling rate ADC 130 generates adequate sampling results S_{SPL} of the received signal S_{RX}.

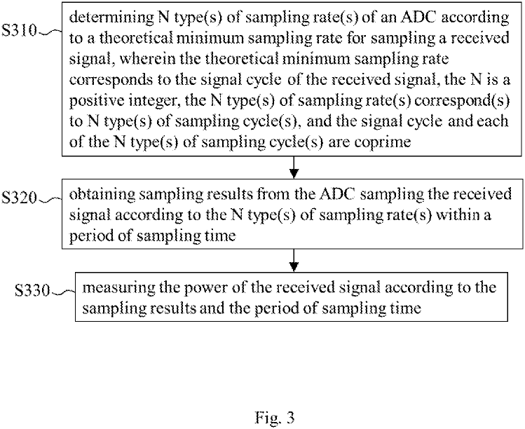

FIG. 3 shows an embodiment of the method of the present disclosure for measuring the power of a received signal. This embodiment can be performed by the wireless receiver 100 of FIG. 1 or the equivalent thereof, and it is applicable to a circumstance that the signal cycle of the received signal can be ascertained. The embodiment includes the following steps:

S310: determining N type(s) of sampling rate(s) of an ADC (e.g., the low sampling rate ADC 130 in FIG. 1) according to a theoretical minimum sampling rate (e.g., the aforementioned ƒ_{S_MIN}) of the received signal, wherein the theoretical minimum sampling rate corresponds to the signal cycle of the received signal, the N is a positive integer, the N type(s) of sampling rate(s) correspond(s) to N type(s) of sampling cycle(s), and the signal cycle (i.e., a product of a signal-cycle coefficient and a unit of time) and each of the N type(s) of sampling cycle(s) (i.e., a product of a sampling-cycle coefficient and the unit of time, wherein the sampling-cycle coefficient varies with the type of sampling cycle) are coprime (i.e., the signal-cycle coefficient and the sampling-cycle coefficient are coprime). For example, when the N is one, the signal cycle is T_{S}, and the sampling cycle is T₁, the signal cycle T_{S} (i.e., α × ΔT, wherein α is a signal-cycle coefficient and ΔT is a unit of time) and the sampling cycle T₁ (i.e., β × ΔT, wherein β is a sampling-cycle coefficient and ΔT is the unit of time) are coprime (i.e., α and β are coprime). For example, when the N is greater than one, the signal cycle is T_{S}, and the N types of sampling cycles are T₁, T₂, ..., and T_{N}, the signal cycle T_{S} and each of the N types of sampling cycles T₁, T₂, ..., and T_{N} are coprime.

S320: obtaining sampling results from the ADC sampling the received signal according to the N type(s) of sampling rate(s) within a period of sampling time. To be more specific, the ADC obtains one or more sampling result(s) according to each sampling rate within the period of sampling time, and thereby the ADC obtains the sampling results according to all sampling rate(s) (i.e., the N type(s) of sampling rate(s)). For example, the N type(s) of sampling rate(s) correspond(s) to N type(s) of sampling cycle(s); when the N is one, the N type(s) of sampling cycle(s) is a certain sampling cycle, and the total number of the sampling results is not less than the numerical value of the certain sampling cycle. For example, the N type(s) of sampling rate(s) correspond(s) to N type(s) of sampling cycle(s); when the N is greater than one, the total number of the sampling results is not less than the numerical value of the maximum sampling cycle of the N types of sampling cycles. It is noted that the unit of each sampling cycle is centisecond/millisecond/microsecond or determined according to implementation needs.

S330: measuring the power of the received signal according to the sampling results and the period of sampling time. For example, the step S330 includes: calculating and adding up power according to the sampling results and thereby obtaining total power; and dividing the total power by the period of sampling time and thereby obtaining average power as the power of the received signal.

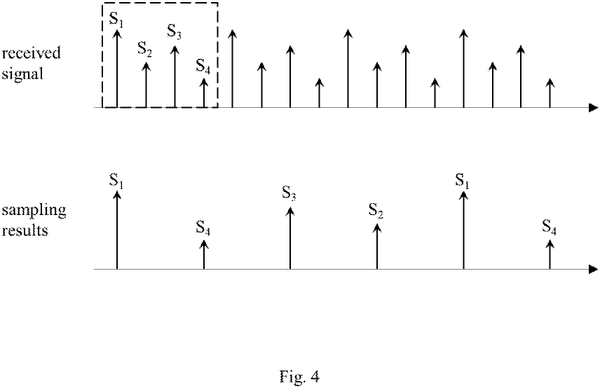

FIG. 4 shows the sampling results obtained with the method of FIG. 3. In regard to the embodiment of FIG. 3, the theoretical minimum sampling rate of the received signal is ƒ_{S_MIN}, the signal cycle of the received signal is

$$\frac{1}{{f}_{S \text{\_} M I N}} = {T}_{S} ,$$

the ADC mentioned in the step S310 samples the received signal according to a single sampling rate

$$\frac{{f}_{S \text{\_} M I N}}{3} ,$$

and the corresponding sampling cycle is

$$\frac{3}{{f}_{S \text{\_} M I N}} = K \times {T}_{S} = 3 {T}_{S} .$$

The received signal is periodic (as illustrated with the dashed box in FIG. 4) and can be represented by four sampling results S₁, S₂, S₃, and S₄ which repeat periodically. As shown in FIG. 4, the sampling results of the ADC includes the first sampling result S₁, the fourth sampling result S₄, the third sampling result S₃, the second sampling result S₂, and so on and so forth. Accordingly, the sampling results of the ADC include the four sampling results S₁, S₂, S₃, and S₄ and are sufficient to represent the received signal. As a result, the power measurement circuit 140 can correctly measure the power of the received signal according to the sampling results of the ADC. It is noted that the signal cycle T_{S} (i.e., T_{S} = 1 × ΔT, wherein 1 is the signal-cycle coefficient and ΔT is the unit of time) and the sampling cycle 3T_{S} (i.e., 3T_{S} = 3 × ΔT, wherein 3 is a sampling-cycle coefficient and ΔT is the unit of time) are coprime, which means that T_{S} is not divisible by 3T_{S}.

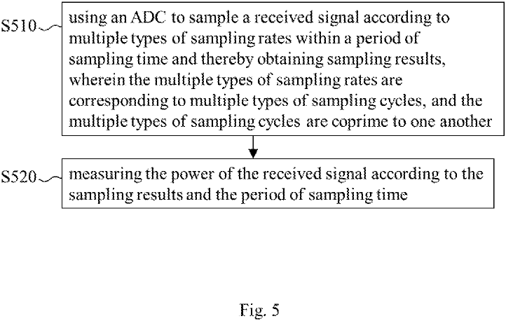

FIG. 5 shows another embodiment of the method of the present disclosure for measuring the power of a received signal. This embodiment can be performed by the wireless receiver 100 of FIG. 1 or the equivalent thereof, and it is applicable to a circumstance that the signal cycle of the received signal is uncertain or not required. The embodiment includes the following steps:

S510: using an ADC (e.g., the low sampling rate ADC 130 in FIG. 1) to sample the received signal according to multiple types of sampling rates within a period of sampling time and thereby obtaining sampling results, wherein the multiple types of sampling rates are corresponding to multiple types of sampling cycles (e.g., 3T_{S}, 7T_{S}, 11T_{S},...), and the multiple types of sampling cycles are coprime to one another. For example, the period of sampling time is not shorter than the maximum sampling cycle of the multiple types of sampling cycles. For example, the multiple types of sampling cycles are 2T_{S}, 3T_{S}, and 5T_{S}, and the ADC sampled the received signal every 2T_{S}, every 3T_{S}, and every 5T_{S}.

S520: measuring the power of the received signal according to the sampling results and the period of sampling time. This step is similar to the step S330.

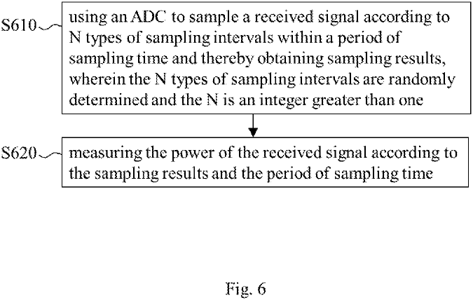

FIG. 6 shows yet another embodiment of the method of the present disclosure for measuring the power of a received signal. This embodiment can be performed by the wireless receiver 100 of FIG. 1 or the equivalent thereof, and it is applicable to a circumstance that the signal cycle of the received signal is uncertain or not required. The embodiment includes the following steps:

S610: using an ADC (e.g., the low sampling rate ADC 130 in FIG. 1) to sample the received signal according to N types of sampling intervals (e.g., 2T, 3T, and 5T, wherein 2, 3, and 5 are coefficients, and T is a given unit of time) within a period of sampling time and thereby obtaining sampling results, wherein the N types of sampling intervals are randomly determined and the N is an integer greater than one. In an exemplary implementation, the total number of the sampling results is not less than the maximum value of the N types of sampling intervals. It is noted that the N types of sampling intervals can be determined in a pseudo-random manner or in a true-random manner. It is also noted that the ADC can be a known ADC or a self-developed ADC.

S620: measuring the power of the received signal according to the sampling results and the period of sampling time. This step is similar to the step S330.

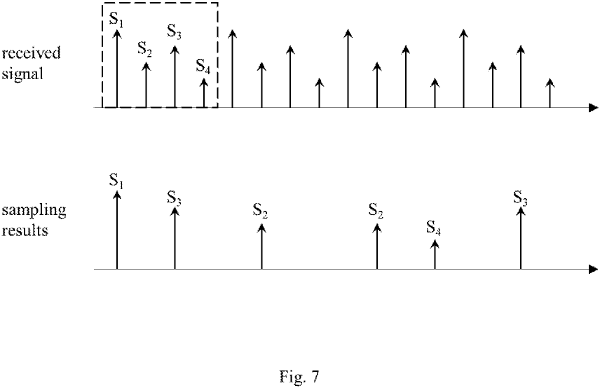

FIG. 7 shows sampling results obtained with the method of FIG. 6. Regarding the embodiment of FIG. 6, the theoretical minimum sampling rate of the received signal is ƒ_{S_MIN}, the signal cycle of the received signal is

$$\frac{1}{{f}_{S \text{\_} M I N}} = {T}_{S} ,$$

and the ADC mentioned in the step S610 samples the received signal according to sampling intervals that are determined randomly. The received signal is periodic (as illustrated with the dashed box in FIG. 7) and can be recovered by at least four sampling results S₁, S₂, S₃, and S₄. As shown in FIG. 7, the sampling results of the ADC includes the first sampling result S₁, the third sampling result S₃, the second sampling result S₂, the second sampling result S₂, the fourth sampling result S₄, the third sampling result S₃, etc. Accordingly, the sampling results of the ADC include the four sampling results S₁, S₂, S₃, and S₄ and are sufficient to represent the received signal provided that the period of sampling time is long enough, that is to say that the N is great enough. As a result, the power measurement circuit 140 can correctly measure the power of the received signal according to the sampling results of the ADC.

It is noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

To sum up, the method of the present disclosure can measure the power of a received signal at an extraordinarily low sampling rate and thereby allow a wireless receiver using the method to reduce its power consumption.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A method for measuring power of a received signal comprising:
determining N type(s) of sampling rate(s) of an analog-to-digital converter (ADC) according to a theoretical minimum sampling rate of the received signal;
obtaining sampling results from the ADC sampling the received signal according to the N type(s) of sampling rate(s) within a period of sampling time; and
measuring the power of the received signal according to the sampling results and the period of sampling time,
wherein the theoretical minimum sampling rate corresponds to a signal cycle of the received signal, the N is a positive integer, the N type(s) of sampling rate(s) correspond(s) to N type(s) of sampling cycle(s), the signal cycle is equivalent to a product of a signal-cycle coefficient and a unit of time, any of the N type(s) of sampling cycle(s) is equivalent to a product of a sampling-cycle coefficient and the unit of time, and the signal-cycle coefficient and the sampling-cycle coefficient are coprime.

2. The method of claim 1, wherein the theoretical minimum sampling rate is equal to two times a bandwidth of the received signal.

3. The method of claim 1, wherein when the N is equal to one, the N type of sampling cycle is a certain sampling cycle, and a total number of the sampling results is not less than a numerical value of the certain sampling cycle; and when the N is greater than one, the total number of the sampling results is not less than a numerical value of a maximum sampling cycle of the N types of sampling cycles.

4. The method of claim 1, wherein the step of measuring the power of the received signal includes:
calculating and adding up power according to the sampling results and thereby obtaining total power; and
dividing the total power by the period of sampling time and thereby obtaining average power as the power of the received signal.

5. A method for measuring power of a received signal, the method being performed by a wireless receiver and comprising:
using an analog-to-digital converter (ADC) to sample the received signal according to multiple types of sampling rates within a period of sampling time and thereby obtaining sampling results, wherein the multiple types of sampling rates are corresponding to multiple types of sampling cycles, and the multiple types of sampling cycles are coprime to one another; and
measuring the power of the received signal according to the sampling results and the period of sampling time.

6. The method of claim 5, wherein the period of sampling time is not shorter than a maximum sampling cycle of the multiple types of sampling cycles.

7. The method of claim 5, wherein the step of measuring the power of the received signal includes:
calculating and adding up power according to the sampling results, and thereby obtaining total power; and
dividing the total power by the period of sampling time and thereby obtaining average power as the power of the received signal.

8. A method for measuring power of a received signal, the method being performed by a wireless receiver and comprising:
using an analog-to-digital converter (ADC) to sample the received signal according to N types of sampling intervals within a period of sampling time and thereby obtaining sampling results, wherein the N types of sampling intervals are randomly determined and the N is an integer greater than one; and
measuring the power of the received signal according to the sampling results and the period of sampling time.

9. The method of claim 8, wherein the period of sampling time is not shorter than a maximum value of the N types of sampling intervals.

10. The method of claim 8, wherein the step of measuring the power of the received signal includes:
calculating and adding up power according to the sampling results, and thereby obtaining total power; and
dividing the total power by the period of sampling time and thereby obtaining average power as the power of the received signal.
